(19) United States
(12) Patent Application Publication
(10) Pub. No.: US 2016/0122871 A1
(43) Pub. Date: May 5, 2016

(54) Atomic Layer Deposition (ALD) Apparatus

(71) Applicants: Sang Hoon Lee, Seongnam-si (KR); Jin Gyun Kim, Suwon-si (KR); Hyun Jin Shin, Seoul (KR); Han Vit Yang, Suwon-si (KR); Yong Seok Cho, Yongin-si (KR)

(72) Inventors: Sang Hoon Lee, Seongnam-si (KR); Jin Gyun Kim, Suwon-si (KR); Hyun Jin Shin, Seoul (KR); Han Vit Yang, Suwon-si (KR); Yong Seok Cho, Yongin-si (KR)

(21) Appl. No.: 14/743,101

(22) Filed: Jun. 18, 2015

(30) Foreign Application Priority Data
Oct. 31, 2014 (KR) 10-2014-0150657

(51) Int. Cl. C23C 16/455; C23C 16/50; H01J 37/32; C23C 16/52

(52) U.S. Cl. CPC C23C 16/45544; C23C 16/52; C23C 16/50; H01J 37/32449; H01J 37/32009

(57) ABSTRACT

An atomic layer deposition (ALD) apparatus includes a first process chamber in which a substrate is accommodated, a plasma generating unit provided on the outside of the first process chamber, a source gas supply unit provided on an upper portion of the plasma generating unit, and configured to supply a plurality of source gases, a purge gas supply unit configured to supply a purge gas to the first process chamber, and a gas control unit configured to control the supply of the source gases and the purge gas, wherein the plasma generating unit includes a second process chamber providing a space in which plasma is generated and a plasma antenna inducing a magnetic field in the second process chamber, and the source gases are supplied to the first process chamber through the plasma generating unit.

### CROSS-REFERENCE TO RELATED APPLICATION

This application claims the priority and benefit of Korean Patent Application No. 10-2014-0150657 filed Oct. 31, 2014, with the Korean Intellectual Property Office, the disclosure of which is hereby incorporated herein by reference.

### FIELD

The present inventive concept relates to an atomic layer deposition (ALD) apparatus.

### BACKGROUND

As the degree of integration of semiconductor devices has increased in recent semiconductor manufacturing processes, fine patterns having a high aspect ratio have been able to be formed. In the case of forming a thin film on such patterns, excellent step coverage and thickness uniformity is required in the thin film. To satisfy such requirements, an ALD apparatus has been developed.

An ALD process using an ALD apparatus may prevent a reaction between source gases in a gaseous state by alternately allowing the inflow of two or more source gas into a process chamber sequentially, at predetermined intervals. In other words, in a state in which a single species of source gas is chemically adsorbed onto a substrate surface, another species of source gas subsequently entering the process chamber may react therewith to thereby generate a thin film having a thickness of a monolayer on the substrate surface. By repeatedly performing such a process in a single cycle until a thin film having a desired thickness is obtained, precise control of a thickness and composition of the thin film may be achieved.

Recently, in order to enhance a reactivity of source gases, a plasma enhanced atomic layer deposition (PEALD) apparatus using a plasma technique has been proposed.

### SUMMARY

An exemplary embodiment of the present inventive concept may provide an atomic layer deposition (ALD) apparatus capable of enhancing a reactivity of source gases and depositing a conformal and high-quality thin film in a pattern having a high aspect ratio.

According to an exemplary embodiment of the present inventive concept, an ALD apparatus may include: a first process chamber in which a substrate is accommodated; a plasma generating unit provided on the outside of the first process chamber; a source gas supply unit provided on an upper portion of the plasma generating unit, and supplying a plurality of source gases; a purge gas supply unit supplying a purge gas to the first process chamber; and a gas control unit controlling the supply of the source gases and the purge gas, wherein the plasma generating unit includes a second process chamber providing a space in which plasma is generated and a plasma antenna inducing a magnetic field in the second process chamber, and the source gases are supplied to the first process chamber through the plasma generation unit.

The second process chamber may be formed of an insulating member and may have a cylindrical shape, the plasma antenna may be wound around an outer circumferential surface of the second process chamber in a form of coil, and at least one of the plurality of source gases to the first process chamber in a radical state is supplied by the plasma generating unit.

The plasma generating unit may form a plurality of plasma areas to be spaced apart from one another along a central axis of the second process chamber.

Ions of the source gases may be confined within the second chamber by the plurality of plasma areas.

The plasma generating unit may generate the plasma using an inductively coupled plasma (ICP) scheme.

The ALD apparatus may further include: a high frequency power supply unit supplying high frequency power to the plasma antenna; and an impedance matching unit performing impedance matching between the plasma antenna and the high frequency power supply unit.

The source gas supply unit may supply the plurality of different species of source gases in independent pulses, through being connected to a plurality of source gas lines, respectively.

The first process chamber may include a susceptor on which a substrate is mounted, and the plasma generating unit may be disposed on an upper portion of the first process chamber, and may be spaced apart from the susceptor by a predetermined distance, such that the plasma generated within the plasma generating unit is not in direct contact with the substrate.

The plasma generating unit may supply the plurality of different species of source gas from the upper portion of the first process chamber to the substrate.

The plasma generating unit may be disposed on a side of the first process chamber, and may supply the plurality of source gases from the side of the first process chamber to the substrate.

The plasma generating unit may include a plurality of plasma generating units, such that the plurality of different species of source gas are supplied to the first process chamber in a radical state, and a plurality of substrates are loaded in the first process chamber.

According to another exemplary embodiment of the present inventive concept, an ALD apparatus may include: a first process chamber in which a substrate is loaded; and a plasma generating unit supplying a plurality of different species of source gas to the substrate, and supplying at least one of the plurality of source gases to the first process chamber in a radical state, wherein the plasma generating unit includes a second process chamber formed of an insulating member and having a cylindrical shape and a plasma antenna wound around an outer circumferential surface of the second process chamber in a form of coil, and forms a plurality of plasma areas to be spaced apart from one another along a central axis of the second process chamber.

The plurality of plasma areas may include three areas, and a plasma area disposed in a center thereof may have a highest level of potential.

The plasma antenna may be connected to a high frequency power supply unit supplying high frequency power, and may be wound to have a length corresponding to a wavelength of the high frequency power.

The substrate may include a channel hole pattern having a high aspect ratio, and a thin film deposited on the substrate may be a gate dielectric layer.

### BRIEF DESCRIPTION OF DRAWINGS

The above and other aspects, features and advantages of the present inventive concept will be more clearly understood from the following detailed description taken in conjunction with the accompanying drawings, in which:

FIG. 1 is a schematic cross-sectional view illustrating an atomic layer deposition (ALD) apparatus according to an exemplary embodiment of the present inventive concept;

FIG. 2 is a schematic view illustrating a plasma generating unit of the ALD apparatus according to the exemplary embodiment of the present inventive concept illustrated in FIG. 1;

FIG. 3 is a flowchart illustrating a process of forming a thin film using the ALD apparatus according to the exemplary embodiment of the present inventive concept illustrated in FIG. 1;

FIG. 4 is a timing graph illustrating a process of forming a thin film using the ALD apparatus according to the exemplary embodiment of the present inventive concept illustrated in FIG. 1;

FIG. 5 is a flowchart illustrating a process of forming a thin film using the ALD apparatus according to the exemplary embodiment of the present inventive concept illustrated in FIG. 1;

FIG. 6 is a timing graph illustrating a process of forming a thin film using the ALD apparatus according to the exemplary embodiment of the present inventive concept illustrated in FIG. 1;

FIG. 7 is a cross-sectional view illustrating a thin film formed on a substrate using the ALD apparatus according to the exemplary embodiment of the present inventive concept illustrated in FIG. 1;

FIG. 8 is a schematic cross-sectional view illustrating an ALD apparatus according to an exemplary embodiment of the present inventive concept;

FIG. 9 is a schematic cross-sectional view illustrating an ALD apparatus according to an exemplary embodiment of the present inventive concept;

FIG. 10 is a schematic perspective view illustrating a memory cell structure of a vertical memory device manufactured using an ALD apparatus according to an exemplary embodiment of the present inventive concept;

FIGS. 11A and 11B are views of an enlarged portion of Area A of FIG. 10; and

FIGS. 12 through 20 are views illustrating sequential operations in a method of manufacturing a vertical memory device using an ALD apparatus according to an exemplary embodiment of the present inventive concept.

### DETAILED DESCRIPTION

Hereinafter, exemplary embodiments of the present inventive concept will be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements. In the present inventive concept, terms such as “top surface,” “upper portion,” “lower surface,” “below,” “lateral surface,” “side wall,” and the like, are determined based on the drawings, and in actuality, the terms may be changed according to a direction in which a light emitting device is disposed in actuality.

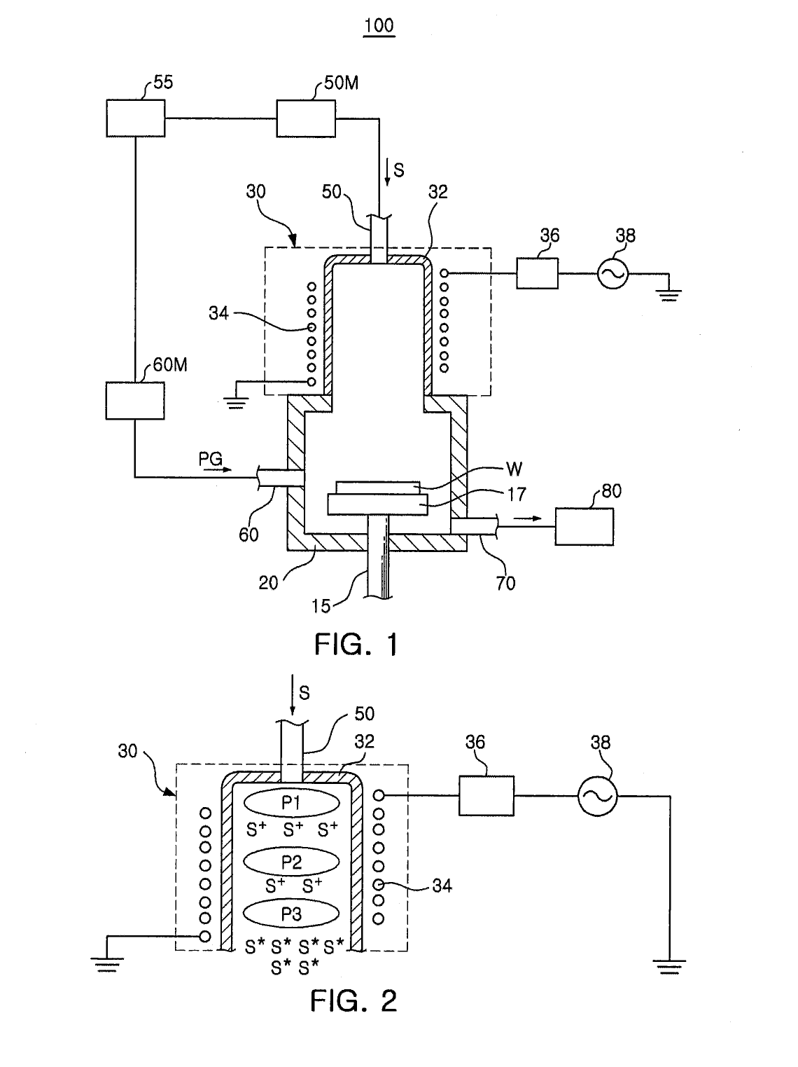

FIG. 1 is a schematic cross-sectional view illustrating an atomic layer deposition (ALD) apparatus according to an exemplary embodiment of the present inventive concept.

Referring to FIG. 1, an ALD apparatus 100 according to an exemplary embodiment of the present inventive concept may include a first process chamber 20, a susceptor 17, and a plasma generating unit 30.

The first process chamber 20 may provide a space in which a substrate W is accommodated and a thin film deposition process is performed. In detail, the first process chamber 20 may provide a space for performing an ALD process.

A purge gas supply unit 60 purging an unreacted source gas S, reaction byproducts which may be generated in the thin film deposition process, and the like, may be provided on a side of the first process chamber 20. A purge gas PG may be injected through the purge gas supply unit 60 in a direction parallel to a surface of the substrate W. The injection of the purge gas PG through the purge gas supply unit 60 may be adjusted by a purge gas adjusting unit 60M.

In addition, an exhaust port 70 through which the unreacted source gas S, the purge gas PG, and the reaction byproducts are discharged may be provided on a side of a lower portion of the first process chamber 20. The exhaust port 70 may be connected to a vacuum pump 80 in order to discharge gases within the first process chamber 20 externally.

The susceptor 17 may be provided within the first process chamber 20 such that the substrate W is mounted on the susceptor 17, and may be rotated by a rotation driving unit 15 supporting the susceptor 17. The susceptor 17 may include a heat supply unit applying heat to the substrate W to adjust a deposition temperature of a thin film.

The plasma generating unit 30 may be provided on the outside of the first process chamber 20, and more particularly, may be provided on the first process chamber 20. The plasma generating unit 30 may be spaced apart from the susceptor 17 by a predetermined distance, such that plasma formed within the plasma generating unit 30 is not in direct contact with the substrate W. The plasma generating unit 30 may include a second process chamber 32 providing a space in which a source gas S is injected to generate plasma therein, and a plasma antenna 34 wound around an outer circumferential surface of the second process chamber 32 in a form of coil so as to induce a magnetic field to be generated in the second process chamber 32. The plasma generating unit 30 may generate the plasma using an inductively coupled plasma (ICP) scheme.

The second process chamber 32 may have a cylindrical shape, and may be formed of an insulating member. For example, such an insulating member may be quartz.

A high frequency power supply unit 38 supplying high frequency power may be connected to the plasma antenna 34. An impedance matching unit 36 may further be provided between the plasma antenna 34 and the high frequency power supply unit 38 to perform impedance matching therebetween.

A source gas supply unit 50 through which a source gas S is injected may be provided on an upper portion of the plasma generating unit 30. The source gas supply unit 50 may be connected to a plurality of source gas lines to supply different source gas in independent pulses to the plasma generating unit 30, respectively. The injection of the source gas S through the source gas supply unit 50 may be adjusted by a source gas adjusting unit 50M.

The first process chamber 20 and the plasma generating unit 30 may be interconnected with one another, and a plurality of source gases S may be supplied to the first process chamber 20 through the plasma generating unit 30. At least one of the plurality of source gases S may be converted into a plasma state within the plasma generating unit 30, and a radical component in the plasma may be supplied to the first process chamber 20.

The ALD apparatus 100 according to the exemplary embodiment may further include a gas control unit 55 controlling the supply of the source gas S and the purge gas PG. In detail, the gas control unit 55 may control the supply of the source gas S and the purge gas PG by controlling the source gas adjusting unit 50M and the purge gas adjusting unit 60M, respectively.

FIG. 2 is a schematic view illustrating the plasma generating unit 30 of the ALD apparatus 100 according to the exemplary embodiment of the present inventive concept illustrated in FIG. 1.

Referring to FIG. 2, the plasma generating unit 30 may form a plurality of plasma areas P1, P2, and P3 to be spaced apart from one another along a central axis of the second process chamber 32.

The plasma antenna 34 wound around an outer circumferential surface of the second process chamber 32 in a form of coil may be formed to have a length corresponding to a wavelength of the high frequency power. When the high frequency power is supplied to the plasma antenna 34 having the length corresponding to the wavelength of the high frequency power, a high frequency current and a high frequency voltage constituting the high frequency power may form standing waves, respectively. The high frequency current and the high frequency voltage may have a phase difference of 90 degrees. A strong induced electric field may be formed within the second process chamber 32, corresponding to an area in which a maximum amplitude is formed in the standing wave of the high frequency current. The area in which the maximum amplitude is formed in the standing wave of the high frequency current may include three areas, and correspondingly thereto, three strong induced electric fields may be formed within the second process chamber 32.

Due to the three strong induced electric fields, the plasma generating unit 30 may form the three plasma areas P1, P2, and P3. The plasma area P2 disposed in the center of the plasma areas P1, P2, and P3 may have a highest level of potential. As such, due to the plurality of plasma areas P1, P2, and P3 having different levels of potentials, ions S* may be confined within the second process chamber 32, and only a radical S*, that is, a neutral particle, therein may enter the first process chamber 32.

Hereinafter, a method of forming a thin film using the ALD apparatus according to the exemplary embodiment illustrated in FIG. 1 having the aforementioned configuration will be described. In detail, a method of forming a thin film through an ALD process using an ALD apparatus according to an exemplary embodiment will be described.

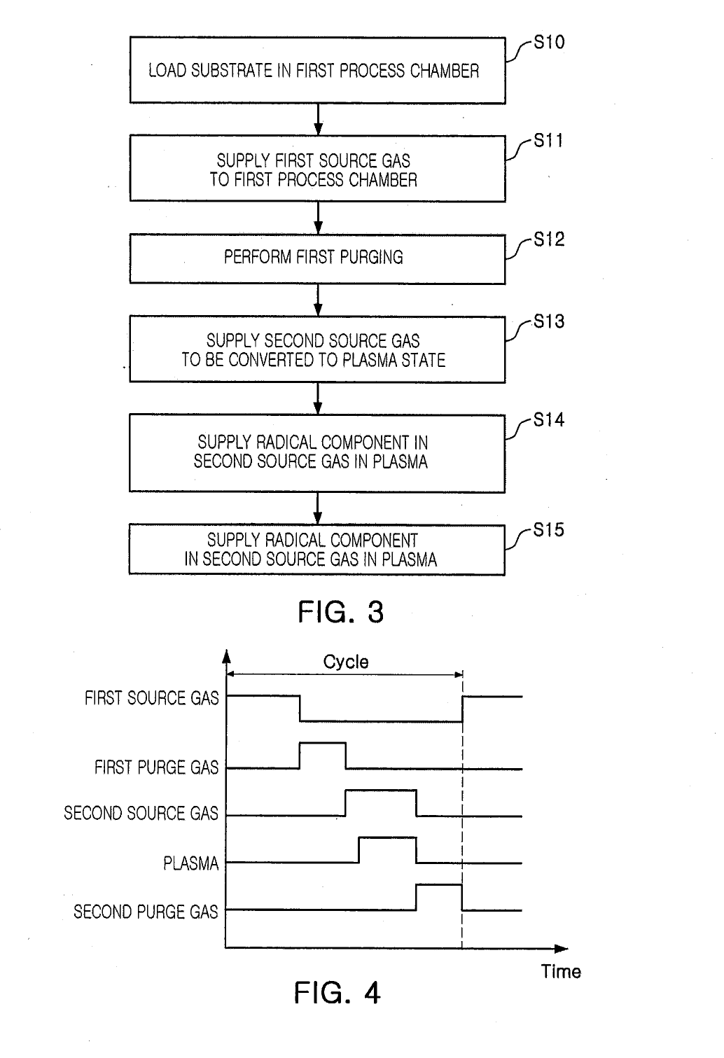

FIG. 3 is a flowchart illustrating a process of forming a thin film using the ALD apparatus according to the exemplary embodiment of the present inventive concept illustrated in FIG. 1; and FIG. 4 is a timing graph illustrating a process of forming a thin film using an ALD apparatus according to an exemplary embodiment of the present inventive concept.

Referring to FIGS. 3 and 4, in operation S10, the substrate W may be loaded in the first process chamber 20. The substrate W may include a pattern having a high aspect ratio formed therein. The aspect ratio may be, for example, higher than 10:1. The pattern may have various shapes such as a cylindrical shape or a linear shape.

Subsequently, an interior of the first process chamber 20 may obtain a predetermined vacuum state by the vacuum pump 80 connected to the exhaust port 70. On the other hand, the substrate W may be heated up to a predetermined process temperature by the heat supply unit included in the susceptor 17.

Thereafter, in operation S11, a first source gas may be supplied to the first process chamber 20. The first source gas may be injected through the source gas supply unit 50 disposed on an upper portion of the second process chamber 32 to be supplied to the first process chamber 20 via the second process chamber 32. The first source gas may be supplied in a pulse during a predetermined period of time so as to be adsorbed onto the substrate W. The first source gas may be a precursor gas of a material forming a thin film. The supplying of the source gas in a pulse during a predetermined period of time may refer to supplying a source gas during only a predetermined period of time at a predetermined flow rate and then blocking the supply thereof, and as used herein, those two expressions will be understood to intend the same.

Thereafter, in operation S12, a first purge gas may be injected into the first process chamber 20 to perform a first purging process therein. A first source gas which is not adsorbed onto the substrate W through the first purging process in operation S12 may be discharged through the exhaust port 70. The first purge gas may be injected into the first process chamber 20 through the purge gas supply unit 60 provided on the side of the first process chamber 20. The first purge gas may be injected in a pulse during a predetermined period of time, and the susceptor 17 on which the substrate W is mounted may be rotated while the purge gas is being injected. The first purge gas may use an inert gas such as argon (Ar) or helium (He). When the first purging process in operation S12 is completed, the substrate W may be in a state in which a monolayer of the first source gas is adsorbed thereonto.

Thereafter, in operation S13, a second source gas may be supplied to the second process chamber 32 to be converted into a plasma state. The second source gas may be supplied to the second process chamber 32 through the source gas supply unit 50 in a pulse during a predetermined period of time. In this instance, in order to assist a formation of plasma, a carrier gas, for example, an Ar gas, may be supplied along with the second source gas. The second source gas supplied to the second process chamber 32 may be converted into the plasma state by supplying high frequency power to the plasma antenna 34. The second source gas in the plasma state may include an ion component and a radical component, and may have a high reactivity. As illustrated in FIG. 4, the second source gas may be initially supplied, and after predetermined time elapsing, the high frequency power may be supplied to the plasma antenna 34 to convert the second source gas into the plasma state. In a manner dissimilar thereto, according to exemplary embodiments, the second source gas may be supplied simultaneously with the high frequency power to the plasma antenna 34 to convert the second source gas into the plasma state.

Thereafter, in operation S14, the radical component of the second source gas in the plasma state may be supplied to the first process chamber 20. As described above, the ion component of the second source gas in the plasma state may be confined within the second process chamber 32, and only the radical component of the second source gas may be supplied to the first process chamber 20 interconnected with the second process chamber 32. The radical component of the second source gas supplied to the first process chamber 20 may react with the first source gas adsorbed onto the substrate W so as to form a thin film having a thickness of a monolayer. The second source gas may be a reactant gas reacting with the first source gas, that is, a precursor gas. Upon completion of the supplying of the second source gas, the supplying of the high frequency power may be blocked; however, the manner of supplying the second source gas and the high frequency power is not limited thereto.

Thereafter, in operation S15, a second purge gas may be injected to the first process chamber 20 to perform a second purging process therein.

A second source gas which does not react with the first source gas adsorbed onto the substrate W and reaction byproducts may be discharged through the exhaust port 70 by the second purging process in operation S15. The second purge gas may be injected into the first process chamber 20 through the purge gas supply unit 60 provided on the side of the first process chamber 20. The susceptor 17 on which the substrate W is mounted may be rotated while the second purge gas is being injected. The second purge gas may use an inert gas such as Ar or He.

Operations S11 through S15 may form a single cycle, and the cycle may be repeatedly performed based on a desired thickness of a thin film.

When the desired thickness of the thin film is formed, the substrate W may be cooled to unload the substrate W from the first process chamber 20.

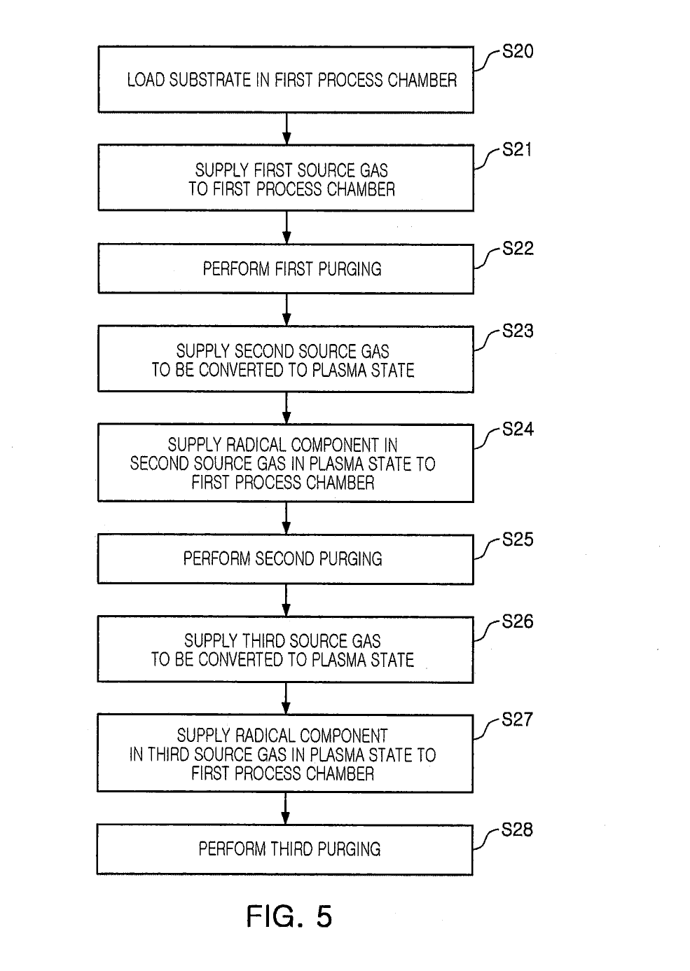

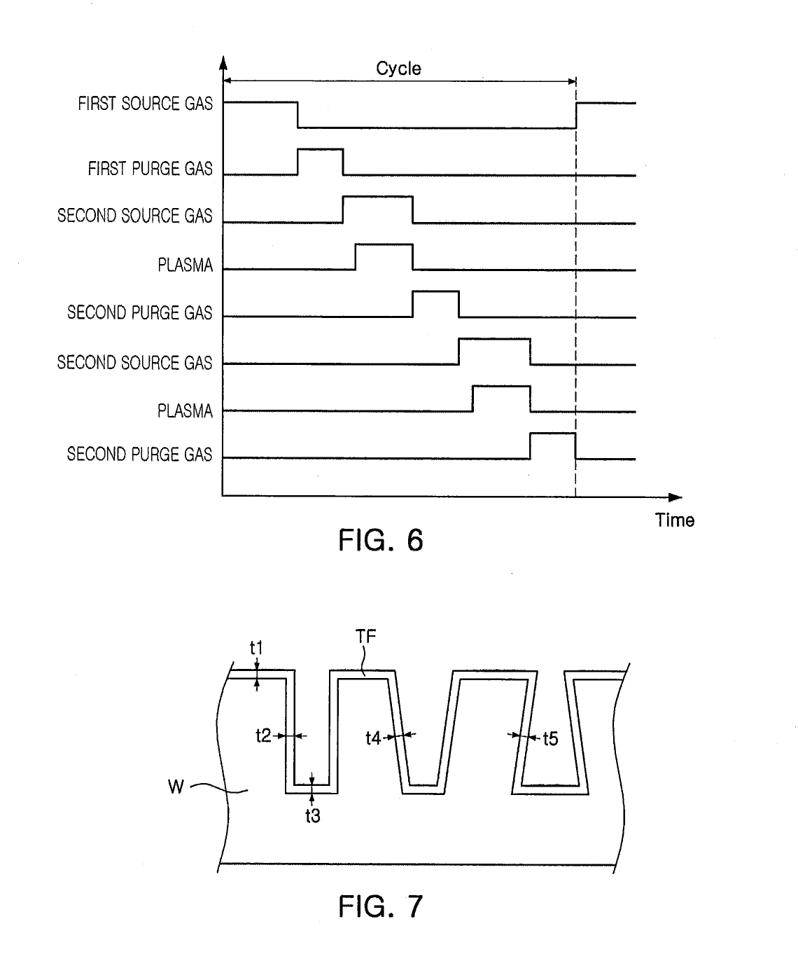

FIG. 5 is a flowchart illustrating a process of forming a thin film using the ALD apparatus according to the exemplary embodiment of the present inventive concept illustrated in FIG. 1; and FIG. 6 is a timing graph illustrating a process of forming a thin film using the ALD apparatus according to the exemplary embodiment of the present inventive concept illustrated in FIG. 1.

Hereinbefore, the method of forming the thin film through the ALD process using the two different source gases, that is, the precursor gas and the single reactant gas, has been described with reference to FIGS. 3 and 4 by way of example. Hereinafter, a method of forming a thin film through the ALD process using three different source gases, that is, a precursor gas and two reactant gases, will be described with reference to FIGS. 5 and 6.

Referring to FIGS. 5 and 6, operations S20 through S25 in which a first source gas and a second source gas are supplied and purged may be performed in the same manner as that described above with reference to FIGS. 3 and 4.

When a second purging process in operation S25 is completed, a third source gas may be supplied to the second process chamber 32 through the source gas supply unit 50 in a pulse during a predetermined period of time. In this instance, in order to assist a formation of plasma, a carrier gas, for example, an Ar gas, may be supplied along with the third source gas. In operation S26, the third source gas supplied to the second process chamber 32 may be converted into a plasma state by supplying high frequency power to the plasma antenna 34. The third source gas in the plasma state may include an ion component and a radical component, and may have a high reactivity. As illustrated in FIG. 6, the third source gas may be initially supplied, and after predetermined time elapsing, the high frequency power may be supplied to the plasma antenna 34 to convert the third source gas into the plasma state. In a manner dissimilar thereto, according to exemplary embodiments, the third source gas may be supplied simultaneously with the high frequency power to the plasma antenna 34 to convert the third source gas into the plasma state.

Thereafter, in operation S27, the radical component of the third source gas in the plasma state may be supplied to the first process chamber 20. As described above, the ion component of the third source gas in the plasma state may be confined within the second process chamber 32, and only the radical component of the third source gas may be supplied to the first process chamber 20 interconnected with the second process chamber 32. The radical component of the third source gas supplied to the first process chamber 20 may additionally react with a material layer formed on the substrate W through a reaction between the first source gas and the second source gas so as to finally form a desired material layer. The third source gas may be a reactant gas additionally reacting with a reactant material of the first source gas and the second source gas. Upon completion of the supplying of the third source gas, the supplying of the high frequency power may be blocked; however, the manner of supplying the third source gas and the high frequency power is not limited thereto.

In operation S28, a third purge gas may be injected to the first process chamber 20 to perform a third purging process therein.

A third source gas which does not react and reaction byproducts may be discharged through the exhaust port 70 by the third purging process in operation S28. The third purge gas may be injected into the first process chamber 20 through the purge gas supply unit 60 provided on the side of the first process chamber 20. The susceptor 17 on which the substrate W is mounted may be rotated while the third purge gas is being injected. The third purge gas may use an inert gas such as Ar or He.

Operations S21 through S28 may form a single cycle, and the cycle may be repeatedly performed based on a desired thickness of a thin film.

When the desired thickness of the thin film is formed, the substrate W may be cooled to unload the substrate W from the first process chamber 20.

FIG. 7 is a cross-sectional view illustrating a thin film formed using the ALD apparatus according to the exemplary embodiment of the present inventive concept illustrated in FIG. 1.

Referring to FIG. 7, a thin film TF having a uniform thickness may be conformally formed on a substrate W including patterns having a high aspect ratio. However, the shape of the patterns is not limited to the illustrated example, and the aspect ratio of the patterns may be higher than 10:1, and a side wall of the patterns may have a vertical slope, a positive slope, or a negative slope. The thickness of the thin film TF formed on the patterns having various shapes may be formed in a uniform manner using the ALD apparatus according to the exemplary embodiment. That is, the thickness of the thin film TF may be substantially identical in all areas of the pattern, irrespective of the shape of the pattern or the slope of the side wall of the pattern. In other words, t1, t2, t3, t4, and t5 may be identical to one another.

For example, the thin film TF may be a silicon compound, and the silicon compound may be a binary silicon compound such as silicon oxide, silicon nitride, and silicon carbide, or a ternary silicon compound such as silicon oxynitride (SiON), silicon boronitride (SiBN), silicon carbonitride (SiCN), and silicon oxycarbide (SiOC). According to exemplary embodiments, the silicon compound may be a quaternary or more silicon compound including Si, O, N, B, or C.

Hereinafter, a case in which the silicon compound is the binary silicon compound will be described with reference to FIGS. 1 and 3.

Referring to FIGS. 1 and 3, the substrate W in which the pattern having the high aspect ratio is formed may be loaded in the first process chamber 20 in operation S10, and a first source gas may be supplied to the first process chamber 20 through the source gas supply unit 50 in a pulse during a predetermined period of time in operation S11. The first source gas may be an organic compound or an inorganic compound including a silicon element. The first source gas may include, for example, hexachlorodisilane (HCDS) or diisopropylaminosilane (DIPAS). The first source gas may be supplied to the substrate W through the second process chamber 32 provided on the first process chamber 20. In this instance, a state in which plasma is not formed in the second process chamber 32 may be maintained therein. In other words, high frequency power may not be supplied to the plasma antenna 34 while the first source gas is being supplied to the first process chamber 20. The first source gas may be adsorbed onto the substrate W in which the pattern is formed. In operation S12, a first purge gas may be supplied to the first process chamber 20 to perform the first purging process therein. The first purge gas may be supplied to the first process chamber 20 through the purge gas supply unit 60 provided on the side of the first process chamber 20. A first source gas which is not adsorbed may be discharged through the exhaust port 70 by the first purging process in operation S12.

Subsequently, in operation S13, a second source gas may be supplied to the second process chamber 32 through the source gas supply unit 50 to be converted into a plasma state. The second source gas may be a gas providing one selected from the group consisting of N, O, and C. For example, the second source gas may be one of oxygen (O₂), ozone (O₃), nitrogen (N₂), ammonia (NH₃), and hydrocarbon (CH). The second source gas may be appropriately selected based on a silicon compound to be formed on the substrate W.

Thereafter, in operation S14, only a radical component of the second source gas in the plasma state may be supplied to the first process chamber 20 in a pulse during a predetermined period of time. The second source gas in a radical state having a high reactivity may react with the first source gas, for example, a silicon source gas, to form the binary silicon compound having a thickness of a monolayer on the substrate W in which the pattern is formed. In operation S15, a second purge gas may be supplied to the first process chamber 20 to perform the second purging process therein. A second source gas which does not react with the first source gas and reaction byproducts may be discharged through the exhaust port 70 by the second purging process in operation S15.

By repeatedly performing operations S11 through S15 based on a desired thickness of the thin film TF, the thin film TF formed of the binary silicon compound may be formed.

Hereinafter, a case in which the silicon compound is the ternary silicon compound will be described with reference to FIGS. 1 and 5. Since the supplying and purging processes of the first and second source gases are the same as those described above with reference to FIGS. 1 and 3, a repeated description thereof will be omitted for conciseness.

Referring to FIGS. 1 and 5, when the second purging process in operation S25 is completed, a third source gas may be supplied to the second process chamber 32 through the source gas supply unit 50 to be converted into a plasma state in operation S26. The third source gas may be a gas selected from the group of N, O, and C, and may be a gas different from the second source gas. For example, the third source gas may be one of O₂, O₃, N₂, NH₃, and CH, and may be a gas other than the gas selected as the second source gas. The second source gas and the third source gas may be appropriately selected based on a silicon compound to be formed on the substrate W.

Thereafter, in operation S27, only a radical component of the third source gas in the plasma state may be supplied to the first process chamber 20 in a pulse during a predetermined period of time. The third source gas in a radical state having a high reactivity may additionally react with a reactant material of the first source gas, for example, a silicon source gas, and the second gas so as to conformally form the ternary silicon compound having a thickness of an atomic layer on the substrate W in which the pattern is formed. In operation S28, a third purge gas may be injected to the first process chamber 20 to perform a third purging process therein. A third source gas which does not react and reaction byproducts may be discharged through the exhaust port 70 by the third purging process in operation S28.

By repeatedly performing operations S21 through S28 based on a desired thickness of the thin film TF, the thin film TF may formed of the ternary silicon compound.

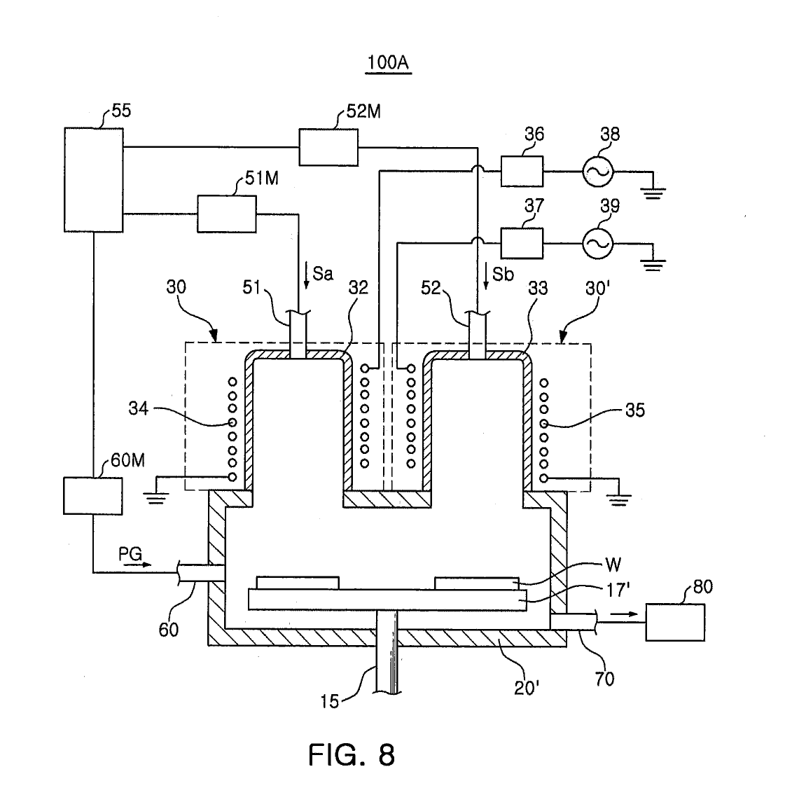

FIG. 8 is a schematic cross-sectional view illustrating an ALD apparatus according to an exemplary embodiment of the present inventive concept.

Referring to FIG. 8, an ALD apparatus 100A according to an exemplary embodiment may include a first process chamber 20′, a susceptor 17′, and first and second plasma generating units 30 and 30′.

The first process chamber 20′ may provide a space in which a substrate W is accommodated and a thin film deposition process is performed. In detail, the first process chamber 20′ may provide a space for performing an ALD process.

A purge gas supply unit 60 purging unreacted source gases Sa and Sb, reaction byproducts which may be generated in the thin film deposition process, and the like, may be provided on a side of the first process chamber 20′. A purge gas PG may be injected through the purge gas supply unit 60 in a direction parallel to a surface of the substrate W. The injection of the purge gas PG through the purge gas supply unit 60 may be adjusted by a purge gas adjusting unit 60M.

In addition, an exhaust port 70 through which the unreacted source gases Sa and Sb, the purge gas PG, and the reaction byproducts which may be generated in the thin film deposition process are discharged may be provided on a side of a lower portion of the first process chamber 20′. The exhaust port 70 may be connected to a vacuum pump 80 in order to discharge gases within the first process chamber 20′ externally.

The susceptor 17′ may be provided within the first process chamber 20′ such that the substrate W is mounted on the susceptor 17′, and may be rotated by a rotation driving unit 15 supporting the susceptor 17′. The susceptor 17′ may have a plurality of substrates W to be mounted thereon. The plurality substrates W may each be rotated on the susceptor 17′ on its own axis. The susceptor 17′ may include a heat supply unit applying heat to an interior of the substrate W to adjust a temperature at which a thin film is formed thereon.

The first and second plasma generating units 30 and 30′ may be provided to convert different source gases into a plasma state and to supply the converted source gases to the first process chamber 20′, respectively. The first and second plasma generating units 30 and 30′ may be provided on an upper portion of the first process chamber 20′ to be spaced apart from one another. The substrates W may be mounted on portions of the susceptor 17′ corresponding to positions of the first and second plasma generating units 30 and 30′, respectively. The first and second plasma generating units 30 and 30′ may be provided to be spaced apart from the susceptor 17′ by a predetermined distance, such that plasma formed within the first and second plasma generating units 30 and 30′ is not in direct contact with the substrate W.

The first plasma generating unit 30 may include a second process chamber 32 providing a space in which a single species of source gas Sa is injected to generate plasma therein, and a plasma antenna 34 wound around an outer circumferential surface of the second process chamber 32 in a form of coil so as to induce a magnetic field to be generated in the second process chamber 32. The second plasma generating unit 30′ may include a second process chamber 33 providing a space in which another single species of source gas Sb is injected to generate plasma therein, and a plasma antenna 35 wound around an outer circumferential surface of the second process chamber 33 in a form of coil so as to induce a magnetic field to be generated in the second process chamber 33.

The first and second plasma generating units 30 and 30′ may independently operate, and may generate the plasmas using an ICP scheme.

The second process chambers 32 and 33 may have a cylindrical shape, and may be formed of an insulating member. For example, such an insulating member may be quartz.

High frequency power supply units 38 and 39 supplying high frequency power may be connected to the plasma antennas 34 and 35. An impedance matching unit 36 may further be provided between the plasma antenna 34 and the high frequency power supply units 38 to perform impedance matching therebetween, and an impedance matching unit 37 may further be provided between the plasma antenna 35 and the high frequency power supply unit 39 to perform impedance matching therebetween.

The first plasma generating unit 30 may form a plurality of plasma areas spaced apart from one another along a central axis of the second process chamber 32, and the second plasma generating unit 30′ may form a plurality of plasma areas spaced apart from one another along a central axis of the second process chamber 33. The plurality of plasma areas included in each of the first and second plasma generating units 30 and 30′ may include three plasma areas. A plasma area disposed in the center of the three plasma areas which are formed in each of the first and second plasma generating units 30 and 30′ may have a highest level of potential. As such, due to the plasma areas having different levels of potentials, ions in the plasma may be confined within the second process chamber 32, and only a radical component, that is, a neutral particle, in the plasma may enter the first process chamber 32.

Source gas supply units 51 and 52 to which the source gases Sa and Sb are injected may be provided on upper portions of the first and second plasma generating units 30 and 30′, respectively. The source gas supply unit 51 may be connected to a plurality of source gas lines to supply different species of source gas Sa in independent pulses to the first plasma generating unit 30, respectively, and the source gas supply unit 52 may be connected to a plurality of source gas lines to supply different species of source gas Sb in independent pulses to the second plasma generating unit 30′, respectively. The injection of the source gases Sa and Sb through the source gas supply units 51 and 52 may be adjusted by source gas adjusting units 51M and 52M, respectively.

The first process chamber 20 is interconnected with the first and second plasma generating units 30 and 30′, and the source gases may be supplied to the first process chamber 20 through the first and second plasma generating units 30 and 30′. At least one of the source gases may be converted into a plasma state in the plasma generating units 30 and 30′, and a radical component in the plasma may be supplied to the first process chamber 20.

The ALD apparatus 100A according to the exemplary embodiment may further include a gas control unit 55 controlling the supply of the source gases Sa and Sb and the purge gas PG. In detail, the gas control unit 55 may control the supply of the source gases Sa and Sb and the purge gas PG by controlling the source gas adjusting units 51M and 52M and the purge gas adjusting unit 60M.

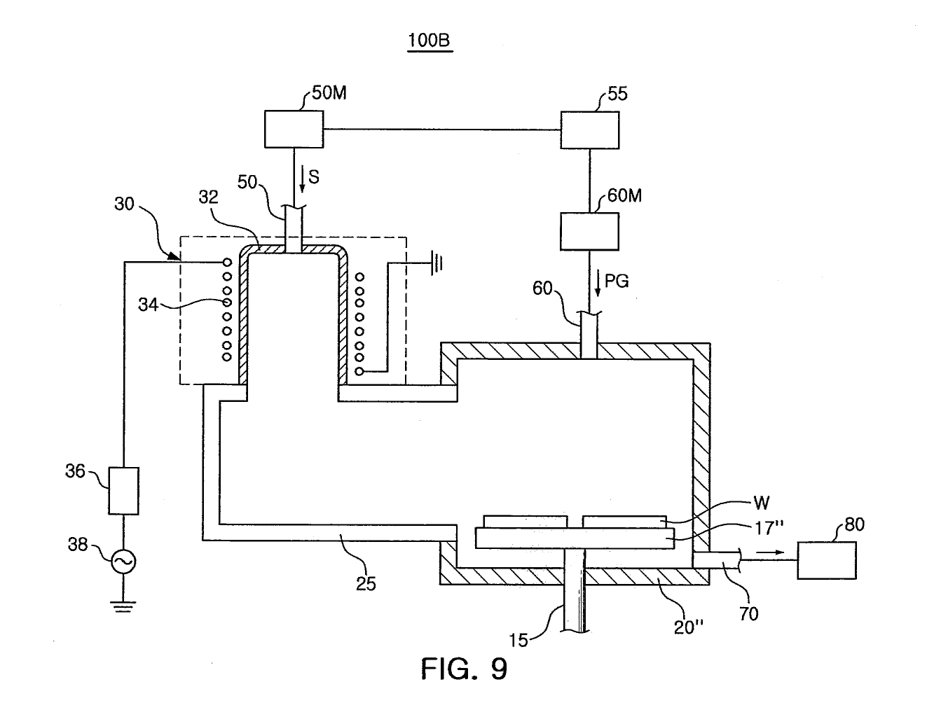

Referring to FIG. 9, an ALD apparatus 100B according to an exemplary embodiment may include a first process chamber 20″, a susceptor 17″, and a plasma generating unit 30.

The ALD apparatus 100B illustrated in FIG. 9 may have a structure in which the plasma generating unit 30 is provided on a side of the first process chamber 20″ in a manner dissimilar to that of the ALD apparatus 100 illustrated in FIG. 1.

The first process chamber 20″ may provide a space in which a substrate W is accommodated and a thin film deposition process is performed. In detail, the first process chamber 20″ may provide a space for performing an ALD process.

A purge gas supply unit 60 purging an unreacted source gas S, reaction byproducts which may be generated in the thin film deposition process, and the like, may be provided on an upper portion of the first process chamber 20″. A purge gas PG may be injected through the purge gas supply unit 60 in a direction perpendicular to a surface of the substrate W. The injection of the purge gas PG through the purge gas supply unit 60 may be adjusted by a purge gas adjusting unit 60M.

In addition, an exhaust port 70 through which the unreacted source gas S, the purge gas PG, and the reaction byproducts are discharged may be provided on a side of a lower portion of the first process chamber 20″. The exhaust port 70 may be connected to a vacuum pump 80 in order to discharge gases within the first process chamber 20″ externally.

The susceptor 17″ may be provided within the first process chamber 20″ such that a plurality of substrates W are mounted on the susceptor 17″, and may be rotated by a rotation driving unit 15 supporting the susceptor 17″. The plurality substrates W may each be rotated on the susceptor 17″ on its own axis. Although not illustrated in FIG. 9, the susceptor 17″ may include a heat supply unit applying heat to an interior of the substrate W to adjust a deposition temperature of a thin film.

The plasma generating unit 30 may be provided on the outside of the first process chamber 20″, and more particularly, may be disposed on the side of the first process chamber 20″, The plasma generating unit 30 may include a second process chamber 32 providing a space in which a source gas S is injected to generate plasma therein, and a plasma antenna 34 wound around an outer circumferential surface of the second process chamber 32 in a form of coil so as to induce a magnetic field to be generated in the second process chamber 32. The plasma generating unit 30 may be interconnected with the first process chamber 20″ through a connection unit 25.

The plasma generating unit 30 may generate the plasma using an ICP scheme.

The second process chamber 32 may have a cylindrical shape, and may be formed of an insulating member. For example, such an insulating member may be quartz.

A high frequency power supply unit 38 supplying high frequency power may be connected to the plasma antenna 34. An impedance matching unit 36 may further be provided between the plasma antenna 34 and the high frequency power supply unit 38 to perform impedance matching therebetween.

A source gas supply unit 50 to which the source gas S is injected may be provided on an upper portion of the second process chamber 32. The source gas supply unit 50 may be connected to a plurality of source gas lines to supply different source gases in independent pulses to the plasma generating unit 30, respectively. The injection of the source gas S through the source gas supply unit 50 may be adjusted by a source gas adjusting unit 50M.

The first process chamber 20″ and the plasma generating unit 30 may be interconnected with one another, and source gases may be supplied to the first process chamber 20 through the plasma generating unit 30. At least one of the source gases may be converted into a plasma state within the plasma generating unit 30, and a radical component in the plasma may be supplied to the first process chamber 20.

The ALD apparatus 100B according to the exemplary embodiment may further include a gas control unit 55 controlling the supply of the source gas S and the purge gas PG. In detail, the gas control unit 55 may control the supply of the source gas S and the purge gas PG by controlling the source gas adjusting unit 50M and the purge gas adjusting unit 60M.

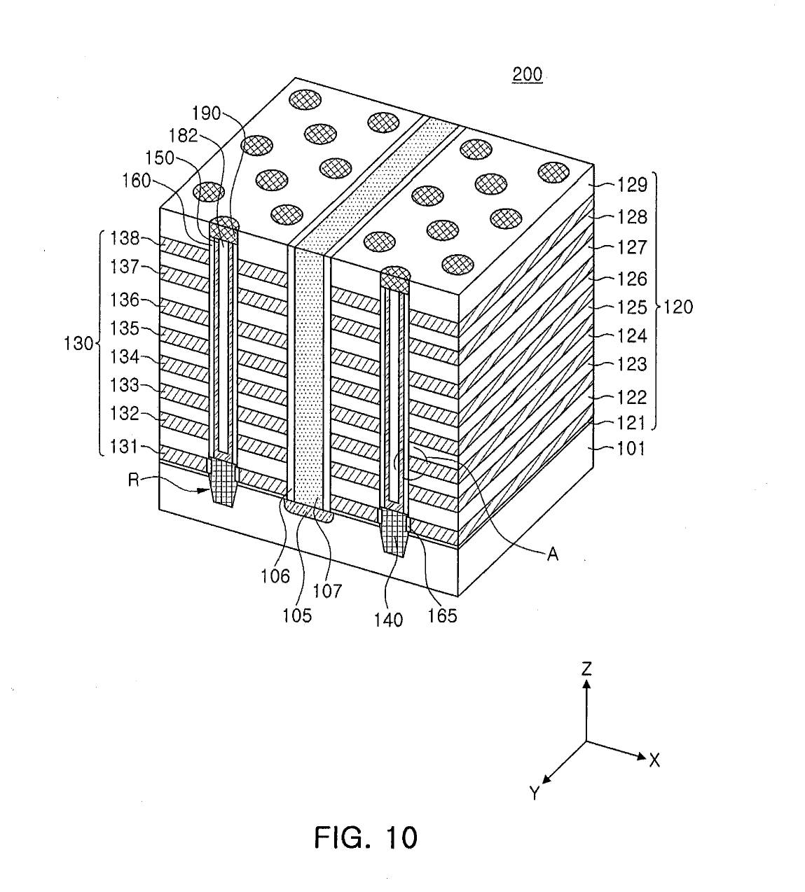

FIG. 10 is a schematic perspective view illustrating a memory cell structure of a vertical memory device manufactured using an ALD apparatus according to an exemplary embodiment of the present inventive concept.

Referring to FIG. 10, a vertical memory device 200 may include a substrate 101, gate structures each including interlayer insulating layers 120 and gate electrodes 130 each of which is alternately stacked on the substrate 101, and channels 150 penetrating through the interlayer insulating layers 120 and the gate electrodes 130 in a direction perpendicular to a top surface of the substrate 101. In addition, the vertical memory device 200 may further include epitaxial layers 140 disposed on the substrate 101 below the channels 150, gate dielectric layers 160 disposed between the channels 150 and the gate electrodes 130, common source lines 107 disposed on source areas 105, and drain pads 190 on the channels 150.

In the vertical memory device 200, a single memory cell string may be provided to be centered on each of the channels 150, and a plurality of memory cell strings may be disposed in an array of rows and columns in an x direction and a y direction.

The substrate 101 may have the top surface extending in the x and y directions. The substrate 101 may include a semiconductor material, for example, a group IV semiconductor, a group III-V compound semiconductor, or a group II-VI semiconductor. For example, the group IV semiconductor may include silicon (Si), germanium (Ge), or silicon germanium (SiGe). The substrate 101 may be provided as a bulk wafer or an epitaxial layer.

The channels 150 having a cylindrical shape may be disposed to extend in a z direction perpendicular to the top surface of the substrate 101. The channels 150 may be formed in an annular manner to encapsulate a first insulating layer 182 therein. The channels 150 may be disposed in a predetermined array in the x and y directions to be spaced apart from one another. In addition, the channels 150 may be disposed in a symmetrical manner with respect to the common source line 107 as illustrated in FIG. 10.

A lower surface of the channels 150 may be electrically connected to the substrate 101 through the epitaxial layers 140. The channels 150 may include a semiconductor material such as polycrystalline silicon, and the semiconductor material may be an undoped material, or a material including p-type or n-type impurities.

The epitaxial layers 140 may be disposed on the substrate 101 below the channels 150. The epitaxial layers 140 may be disposed on lateral surfaces of at least one of the gate electrodes 130. Even though an aspect ratio of the channels 150 is increased, the channels 150 may be electrically connected to the substrate 101 in a stable manner by the epitaxial layers 140. The epitaxial layers 140 may include polycrystalline silicon doped or undoped with impurities, single crystalline silicon, polycrystalline germanium, or single crystalline germanium.

An epitaxial insulating layer 165 may be disposed between the epitaxial layer 140 and a gate electrode 131 which is adjacent to the epitaxial layer 140. The epitaxial insulating layer 165 may be an oxide layer formed by thermal oxidizing a portion of the epitaxial layer 140. For example, the epitaxial insulating layer 165 may be a silicon oxide layer, for example, a SiO2 layer, formed by thermal oxidizing a silicon epitaxial layer 140.

A plurality of gate electrodes 131 through 138 (130) may be disposed to be spaced apart from one another in a z direction from the substrate 101 along lateral surfaces of the respective channels 150. The gate electrodes 130 may include polycrystalline silicon, a metal silicide material, or a metal material. The metal silicide material may be a silicide material of a metal selected from, for example, Co, Ni, Hf, Pt, W, and Ti, or a combination thereof. The metal material may be, for example, W, Al, or Cu.

A plurality of interlayer insulating layers 121 through 129 (120) may each be inserted between the gate electrodes 130. The interlayer insulating layers 120 may be disposed to be spaced apart from one another in the z direction and to extend in the y direction, in a manner similar to that of the gate electrodes 130. The interlayer insulating layers 120 may include an insulating material, such as silicon oxide or silicon nitride.

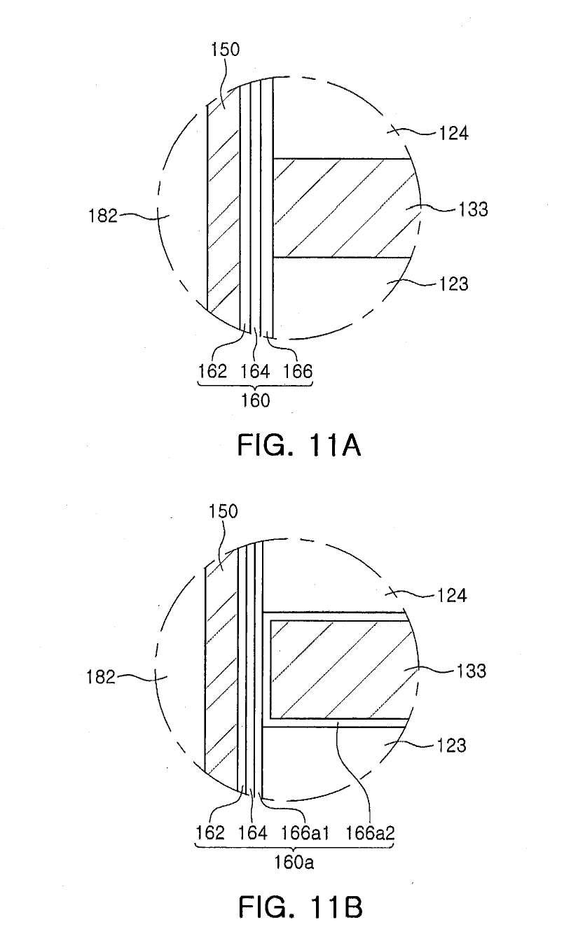

The gate dielectric layer 160 may be disposed between the gate electrodes 130 and the channel 150. Although not illustrated in FIG. 10 in detail, the gate dielectric layer 160 may include a tunneling dielectric layer, an electric charge storing layer, and a blocking dielectric layer sequentially stacked from the channel 150. Hereinafter, a description thereof will be provided with reference to FIGS. 11A and 11B.

FIGS. 11A and 11B are views of an enlarged portion of area A of FIG. 10.

Referring to FIG. 11A, the gate dielectric layer 160 may have a structure in which a tunneling dielectric layer 162, an electric charge storing layer 164, and a blocking dielectric layer 166 are sequentially stacked from the channel 150. The gate dielectric layer 160 may include the tunneling dielectric layer 162, the electric charge storing layer 164, and the blocking dielectric layer 166 which are disposed to extend along the channel 150 in parallel with one another. A thickness of the layers constituting the gate dielectric layer 160 is not limited to the illustrated example, and may change in various manners.

The tunneling dielectric layer 162 may include silicon oxide. The electric charge storing layer 164 may include silicon nitride or silicon oxynitride. The blocking dielectric layer 166 may include silicon oxide, metal oxide having a high-k, or a combination thereof. The metal oxide having a high-k may be, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), praseodymium oxide (Pr₂O₃), or a combination thereof.

Referring to FIG. 11B, a gate dielectric layer 160a may have a structure in which a tunneling dielectric layer 162, an electric charge storing layer 164, and blocking dielectric layers 166a1 and 166a2 are sequentially stacked from the channel 150. In a manner dissimilar to that of the exemplary embodiment in FIG. 8, the blocking dielectric layer may include the two blocking dielectric layers 166a1 and 166a2, and the first blocking dielectric layer 166a1 may be disposed to extend in parallel with the channel 150 and the second blocking dielectric layer 166a2 may be disposed to encapsulate the gate electrode layer 133. For example, the first blocking dielectric layer 166a1 may be a silicon oxide layer, and the second blocking dielectric layer 166a2 may be a metal oxide layer having a high-k.

Referring to FIG. 10 again, in an upper portion of the memory cell string, the drain pad 190 may be disposed to cover the top surface of the first insulating layer 182, and to be electrically connected to the channel 150. The drain pad 190 may include, for example, doped polycrystalline silicon. Although not illustrated in FIG. 10, the drain pad 190 may be electrically connected to a bit line BL formed on the drain pad 190.

In a lower portion of the memory cell string, the source area 105 may be disposed in a portion of the substrate 101. The source area 105 may be arranged to be spaced apart from one another at predetermined intervals in the x direction while extending in the y direction and formed adjacently to the top surface of the substrate 101. For example, a single source area 105 may be provided at the interval of every two channels 150 in the x direction; however, the array of source areas 105 is not limited thereto. The common source line 107 may be disposed on the source area 105 to extend therealong in the y direction. The common source line 107 may include a conductive material. For example, the common source line 107 may include W, Al, or Cu. The common source line 107 may be electrically insulated from the gate electrodes 130 by second insulating layers 106.

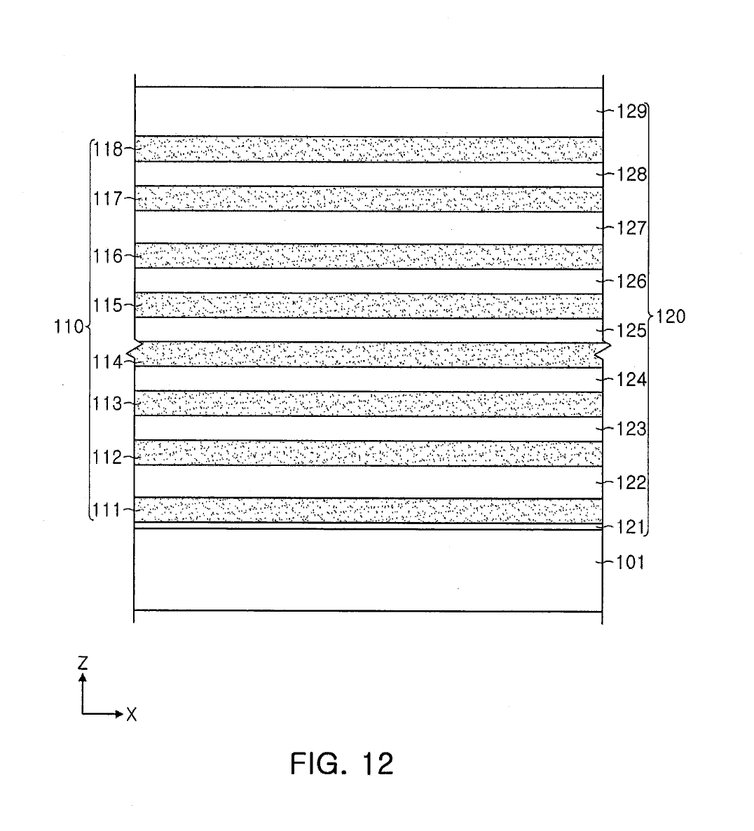

FIGS. 12 through 20 are views illustrating sequential operations in a method of manufacturing a vertical memory device using an ALD apparatus according to an exemplary embodiment of the present inventive concept.

Referring to FIG. 12, sacrificial layers 111 through 118 (110) and the interlayer insulating layers 120 may each be stacked on the substrate 101 alternately. The interlayer insulating layers 120 and the sacrificial layers 110 may each be stacked on the substrate 101 alternately from the first interlayer insulating layer 121.

The sacrificial layers 110 may be formed of an material having etching selectivity with respect to the interlayer insulating layers 120. For example, the interlayer insulating layers 120 may be formed of at least one of silicon oxide and silicon nitride, and the sacrificial layers 110 may be formed of a material selected from silicon, silicon carbide, Silicon oxide, and silicon nitride, and a material different from that forming the interlayer insulating layers 120.

As illustrated in FIG. 12, a thickness of the interlayer insulating layers 120 may not be to the same as one another. The interlayer insulating layer 121 in a lowermost portion of the interlayer insulating layers 120 may be formed to be relatively thin, and an interlayer insulating layer 129 in an uppermost portion of the interlayer insulating layers 120 may be formed to be relatively thick.

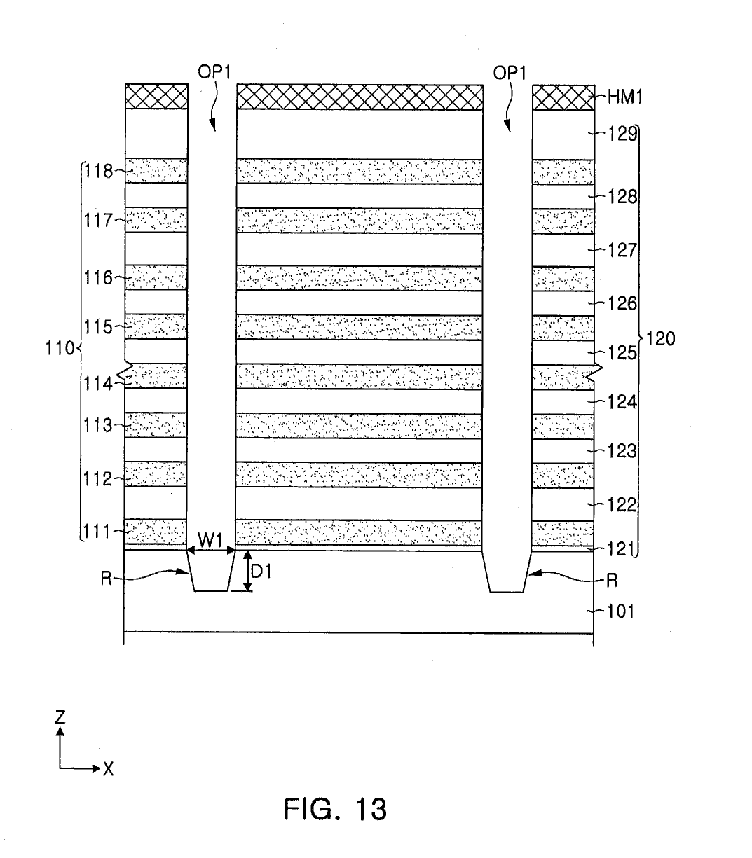

Referring to FIG. 13, first openings OP1 having a high aspect ratio and having a hole shape penetrating through the sacrificial layers 110 and the interlayer insulating layers 120 may be formed. The first opening OP1 may be referred to as a “channel hole”. An aspect ratio of the first opening OP1 may be higher than 10:1.

The first opening OP1 may extend onto the substrate 101 in the z direction so as to form a recess area R within the substrate 101. The first opening OP1 may be formed by performing an anisotropic etching process on the sacrificial layers 110 and the interlayer insulating layers 120. A depth D1 of the recess area R may be determined based on a width W1 of the first opening OP1.

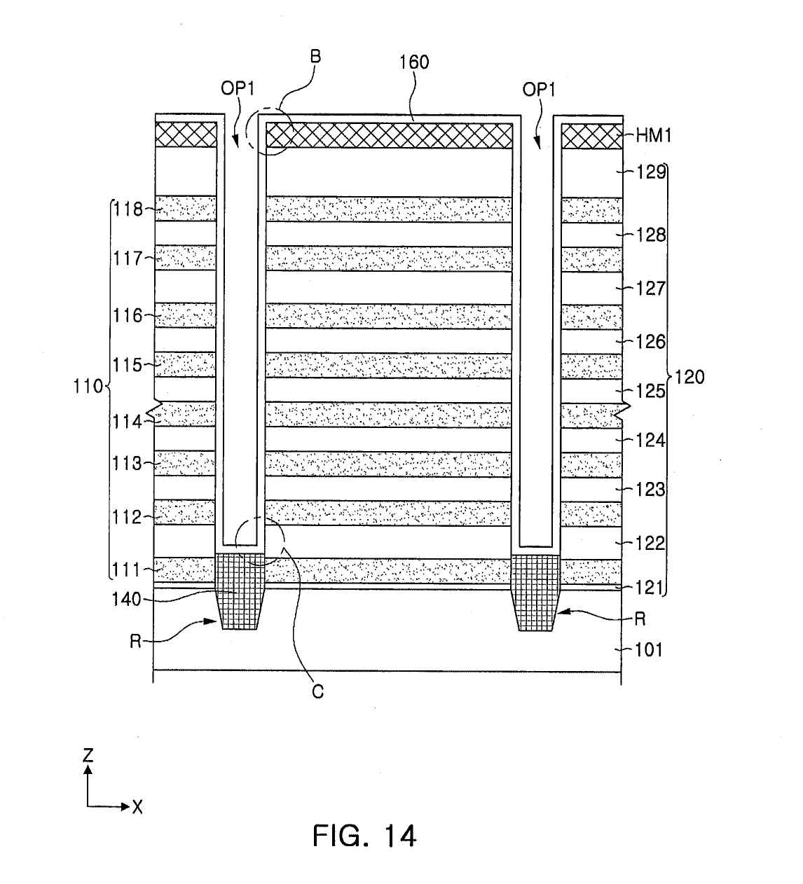

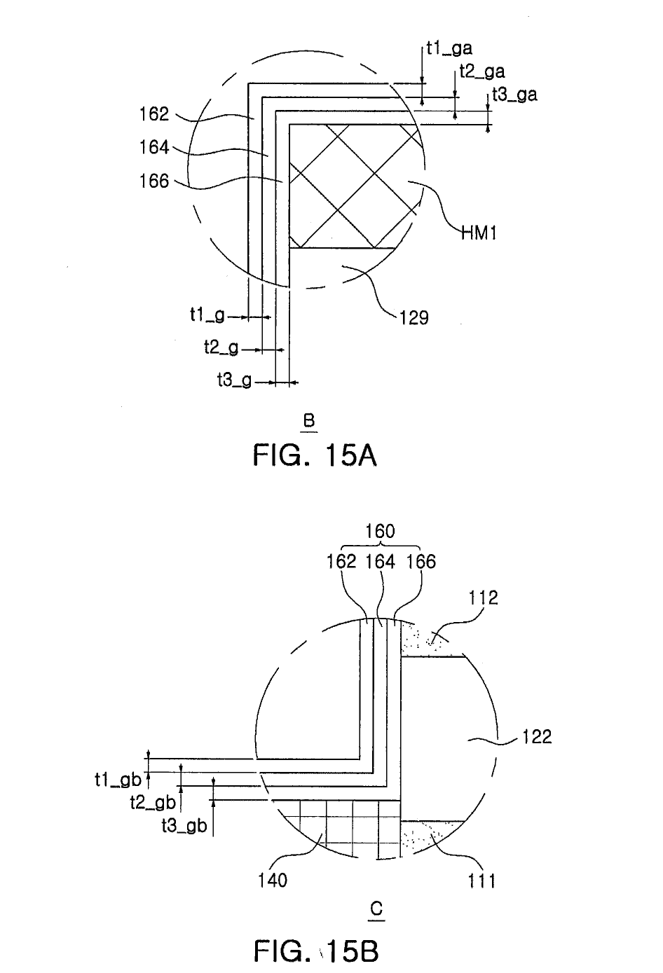

Referring to FIG. 14, the epitaxial layer 140 may be formed within the recess area R in a lower portion of the first opening OP1.

The epitaxial layer 140 may be formed through a selective epitaxial growth (SEG) process. The epitaxial layer 140 may fill the recess area R, and may extend onto the substrate 101. A top surface of the epitaxial layer 140 may be disposed to be higher than the sacrificial layer 111 adjacent to the substrate 101, and may be disposed to be lower than a lower surface of a sacrificial layer 112 above the sacrificial layer 111.

As illustrated in FIG. 14, the top surface of the epitaxial layer 140 may be formed to be flat. However, the top surface of the epitaxial layer 140 may be sloped depending on growth conditions, or the like.

The gate dielectric layer 160 may be formed on an inner side wall of the first openings OP1. The gate dielectric layer 160 may be conformally formed to have a uniform thickness by performing an ALD process using the ALD apparatus illustrated in FIG. 1.

A method of forming the gate dielectric layer 160 having the stacked structure illustrated in FIG. 11A will be described in greater detail with reference to FIGS. 1 and 3.

In detail, the gate dielectric layer 160 may have a structure in which the tunneling dielectric layer 162, the electric charge storing layer 164, and the blocking dielectric layer 166 are stacked while extending along the channel 150. The blocking dielectric layer 166, the electric charge storing layer 164, and the tunneling dielectric layer 162 may be sequentially formed in the first opening OP1.

Firstly, the blocking dielectric layer 166 may be formed on the inner side wall of the first opening OP1. The blocking dielectric layer 166 may be a metal oxide having a high-k, and the metal oxide may be formed by performing the ALD process using the ALD apparatus illustrated in FIG. 1.

Referring to FIGS. 1 and 3, the substrate 101 having the first opening OP1 formed therein may be loaded in the first process chamber 20 in operation S10, and a metal source gas may be supplied to the first process chamber 20 in a pulse during a predetermined period of time in operation S11. The metal source gas may be an organic compound including a metallic element. The metal source gas may include Al, Hf, Zr, La, Ta, or the like. The metal source gas may be supplied to the substrate 101 through the second process chamber 32 provided on the first process chamber 20. In this instance, a state in which plasma is not formed in the second process chamber 32 may be maintained therein. In other words, high frequency power may not be supplied to the plasma antenna 34 while the metal source gas is being supplied to the first process chamber 20. The metal source gas may be adsorbed onto the inner side wall of the first opening OP1, the top surface of the epitaxial layer 140, and a top surface of a hard mask HM1. In operation S12, a first purge gas may be injected to the first process chamber 20 to perform a first purging process therein. The first purge gas may be supplied to the first process chamber 20 through the purge gas supply unit 60 provided on the side of the first process chamber 20. A metal source gas which is not adsorbed may be discharged through the exhaust port 70 by the first purging process in operation S12.

In operation S13, an oxygen source gas may be supplied to the second process chamber 32 through the source gas supply unit 50 to be converted into a plasma state. The oxygen source gas may be selected from the group consisting O₂, O₃, H₂O, and hydrogen peroxide (H₂O₂). In operation S14, only a radical component in the oxygen source gas in the plasma state may be supplied to the first process chamber 20 in a pulse during a predetermined period of time. The oxygen source gas in a radical state having a high reactivity may react with the metal source gas so as to form the metal oxide having a thickness of a monolayer conformally on the inner side wall of the first opening OP1, the top surface of the epitaxial layer 140, and the top surface of the hard mask HM1. In operation S15, a second purge gas may be supplied to the first process chamber 20 to perform a second purging process therein. A second source gas which does not react with the first source gas and reaction byproducts may be discharged through the exhaust port 70 by the second purging process in operation S15.

By repeatedly performing operations S11 through S15 based on a desired thickness of the blocking dielectric layer 166, the blocking dielectric layer 166 formed of the metal oxide may be formed.

Secondly, the electric charge storing layer 164 may be formed on the blocking dielectric layer 166 formed on the inner side wall of the first opening OP1. The electric charge storing layer 164 may be a silicon nitride, and the silicon nitride may be formed by performing the ALD process using the ALD apparatus illustrated in FIG. 1.

Referring to FIGS. 1 and 3, the substrate 101 formed with the first opening OP1 therein having the inner side wall on which the blocking dielectric layer 166 is formed may be loaded in the first process chamber 20 in operation S10, and a silicon source gas may be supplied to the first process chamber 20 in a pulse during a predetermined period of time in operation S11. The silicon source gas may be an organic or inorganic compound including a silicon element. The silicon source gas may include, for example, HCDS, DIPAS, or the like. The silicon source gas may be supplied to the substrate 101 through the second process chamber 32 provided on the first process chamber 20. In this instance, a state in which plasma is not formed in the second process chamber 32 may be maintained therein. In other words, high frequency power may not be supplied to the plasma antenna 34 while the silicon source gas is being supplied to the first process chamber 20. The silicon source gas may be adsorbed onto the blocking dielectric layer 166, on the inner side wall of the first opening OP1, the top surface of the epitaxial layer 140, and the top surface of the hard mask HM1. In operation S12, a first purge gas may be injected to the first process chamber 20 to perform a first purging process therein. The first purge gas may be supplied to the first process chamber 20 through the purge gas supply unit 60 provided on the side of the first process chamber 20. A silicon source gas which is not adsorbed may be discharged through the exhaust port 70 by the first purging process in operation S12.

In operation S13, a nitrogen source gas may be supplied to the second process chamber 32 through the source gas supply unit 50 to be converted into a plasma state. The nitrogen source gas may be one of N₂ and NH₃. In operation S14, only a radical component in the nitrogen source gas in the plasma state may be supplied to the first process chamber 20 in a pulse during a predetermined period of time. The nitrogen source gas in a radical state having a high reactivity may react with the silicon source gas so as to form the silicon nitride having a thickness of a monolayer conformally, on the blocking dielectric layer 166, on the inner side wall of the first opening OP1, the top surface of the epitaxial layer 140, and the top surface of the hard mask HM1. In operation S15, a second purge gas may be supplied to the first process chamber 20 to perform a second purging process therein. A second source gas which does not react with the first source gas and reaction byproducts may be discharged through the exhaust port 70 by the second purging process in operation S15.

By repeatedly performing operations S11 through S15 based on a desired thickness of the electric charge storing layer 164, the electric charge storing layer 164 formed of the silicon nitride may be formed.

Thirdly, the tunneling dielectric layer 162 may be formed on the electric charge storing layer 164 formed on the inner side wall of the first opening OP1. The tunneling dielectric layer 162 may be silicon oxide, and the silicon oxide may be formed by performing the ALD process using the ALD apparatus illustrated in FIG. 1.

Referring to FIGS. 1 and 3, the substrate 101 formed with the first opening OP1 therein having the inner side wall on which the blocking dielectric layer 166 and the electric charge storing layer 164 are formed may be loaded in the first process chamber 20 in operation S10, and a silicon source gas may be supplied to the first process chamber 20 in a pulse during a predetermined period of time in operation S11. The silicon source gas may be an organic or inorganic compound including a silicon element. The silicon source gas may include, for example, HCDS, DIPAS, or the like. The silicon source gas may be supplied to the substrate 101 through the second process chamber 32 provided on the first process chamber 20. In this instance, a state in which plasma is not formed in the second process chamber 32 may be maintained therein. In other words, high frequency power may not be supplied to the plasma antenna 34 while the silicon source gas is being supplied to the first process chamber 20. The silicon source gas may be adsorbed onto the electric charge storing layer 164, on the inner side wall of the first opening OP1, the top surface of the epitaxial layer 140, and the top surface of the hard mask HM1. In operation S12, a first purge gas may be injected to the first process chamber 20 to perform a first purging process therein. The first purge gas may be supplied to the first process chamber 20 through the purge gas supply unit 60 provided on the side of the first process chamber 20. A silicon source gas which is not adsorbed may be discharged through the exhaust port 70 by the first purging process in operation S12.

In operation S13, an oxygen source gas may be supplied to the second process chamber 32 through the source gas supply unit 50 to be converted into a plasma state. The oxygen source gas may be one of O₂, O₃, H₂O, and H₂O₂. In operation S14, only a radical component of the oxygen source gas in the plasma state may be supplied to the first process chamber 20 in a pulse during a predetermined period of time. The oxygen source gas in a radical state having a high reactivity may react with the silicon source gas so as to form the silicon oxide having a thickness of a monolayer conformally, on the electric charge storing layer 164, on the inner side wall of the first opening OP1, the top surface of the epitaxial layer 140, and the top surface of the hard mask HM1. In operation S15, a second purge gas may be supplied to the first process chamber 20 to perform a second purging process therein. A second source gas which does not react and reaction byproducts may be discharged through the exhaust port 70 by the second purging process in operation S15.

By repeatedly performing operations S11 through S15 based on a desired thickness of the tunneling dielectric layer 162, the tunneling dielectric layer 162 formed of the silicon oxide may be formed.

FIGS. 15A and 15B are views illustrating the gate dielectric layer 160 formed by performing the ALD process using the ALD apparatus illustrated in FIG. 1. FIG. 15A is a view of an upper portion, area B, of the first opening OP1, and FIG. 15B is a view of a lower portion, C area, of the first opening OP1. A thickness of the blocking dielectric layer 166 formed using the ALD apparatus according to the exemplary embodiment may each be the same on the top surface of the hard mask HM1, the inner side wall of the first opening OP1, and the top surface of the epitaxial layer 140. That is, a thickness t3_ga of the blocking dielectric layer 166 on the top surface of the hard mask HM1, a thickness t3_g of the blocking dielectric layer 166 on the inner side wall of the first opening OP1, and a thickness t3_gb of the blocking dielectric layer 166 on the top surface of the epitaxial layer 140 may be the same to one another. A thickness t2_ga of the electric charge storing layer 164 on the top surface of the hard mask HM1, a thickness t2_g of the electric charge storing layer 164 on the inner side wall of the first opening OP1, and a thickness t2_gb of the electric charge storing layer 164 on the top surface of the epitaxial layer 140 may be the same as one another. In addition, a thickness t1_ga of the tunneling dielectric layer 162 on the top surface of the hard mask HM1, a thickness t1_g of the tunneling dielectric layer 162 on the inner side wall of the first opening OP1, and a thickness t1_gb of the tunneling dielectric layer 162 on the top surface of the epitaxial layer 140 may be the same as one another.

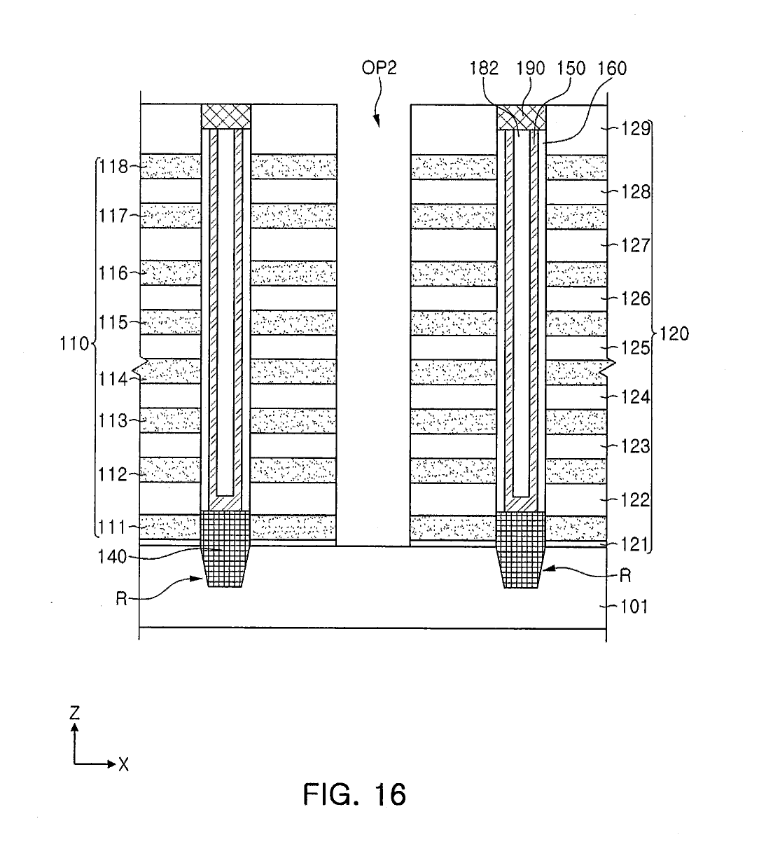

Referring to FIG. 16, a portion of the gate dielectric layer 160 may be removed from the first opening OP1 to expose a portion of the top surface of the epitaxial layer 140, and the channel 150 may be formed on the exposed epitaxial layer 140 and the gate dielectric layer 160. When the portion of the gate dielectric layer 160 is removed, a portion of the epitaxial layer 140 may be removed to form a recess on an upper portion the epitaxial layer 140. The channel 150 may be in contact with the epitaxial layer 140 to be connected to the top surface of the epitaxial layer 140. The channel 150 may be formed using polycrystalline silicon or amorphous silicon. In a case in which the channel 150 is formed using amorphous silicon, a crystallization process may be additionally performed thereon.

The first insulating layer 182 filling the first opening OP1 may be formed, and the drain pad 190 may be formed on the channel 150. The drain pad 190 may be formed by removing portions of the respective first insulating layer 182, the channel 150, and the gate dielectric layer 160, and filling doped polycrystalline silicon therein. A chemical mechanical polishing (CMP) process may be included to expose a top surface of the interlayer insulating layer 129.

A second opening OP2 separating the stacked structure of the sacrificial layers 110 into portions by a predetermined interval and separating the stacked structure of the interlayer insulating layers 120 into portions by a predetermined interval may be formed. The second opening OP2 may be formed by forming a hard mask layer using a photolithography process, and by performing an anisotropic etching process on the stacked structure of the sacrificial layer 110 and the interlayer insulating layer 120. The second opening OP2 may be formed to have a trench shape extending in the y direction (please refer to FIG. 10). Prior to the formation of the second opening OP2, an insulating layer may further be formed on the uppermost interlayer insulating layer 129 and the drain pad 190, whereby damage to the drain pad 190, the channel 150, and the like, may be prevented. The second opening OP2 may expose a portion of the substrate 101 between the channels 150.

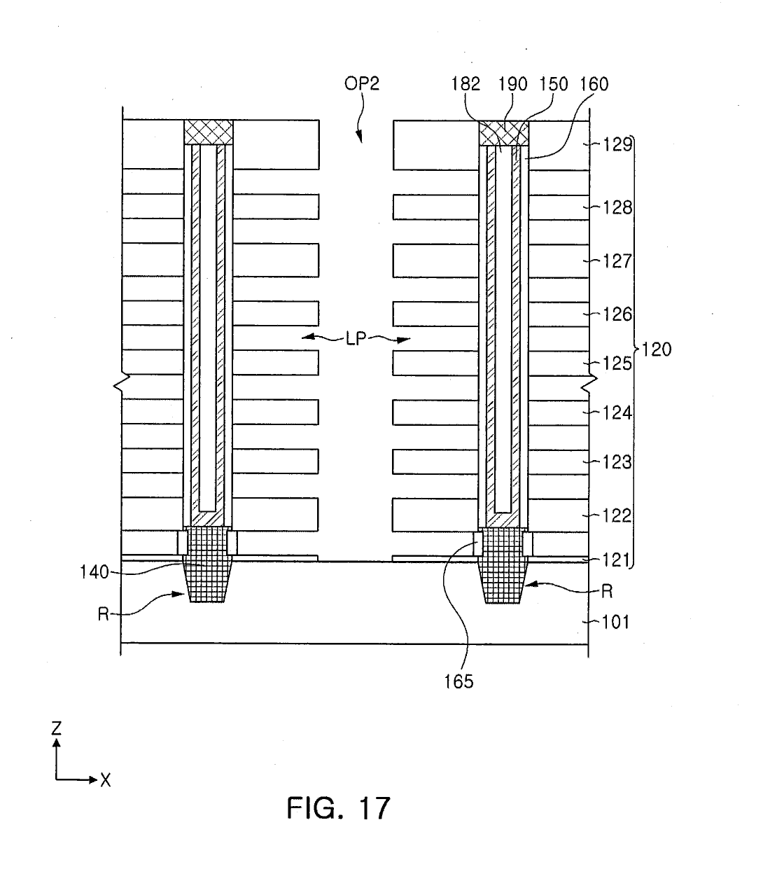

Referring to FIG. 17, the sacrificial layers 110 exposed through the second opening OP2 may be removed using an etching process, whereby lateral openings LP each interposed between the interlayer insulating layers 120 may be formed. Portions of lateral surfaces of the respective gate dielectric layer 160 and the epitaxial layer 140 may be exposed through the lateral openings LP.

Thereafter, the epitaxial insulating layer 165 may be formed on the epitaxial layer 140 exposed through the lateral openings LP. The epitaxial insulating layer 165 may be formed by, for example, a thermal oxidation process. In this instance, the epitaxial insulating layer 165 may be an oxide layer formed by oxidizing a portion of the epitaxial layer 140. A thickness and a shape of the epitaxial insulating layer 165 is not limited to the example illustrated in FIG. 17. In a case in which the thermal oxidation process is performed in the present operation, in a case of the gate dielectric layer 160 exposed through the lateral openings LP, damage incurred to the gate dielectric layer 160 while performing the etching process on the sacrificial layers may be cured.

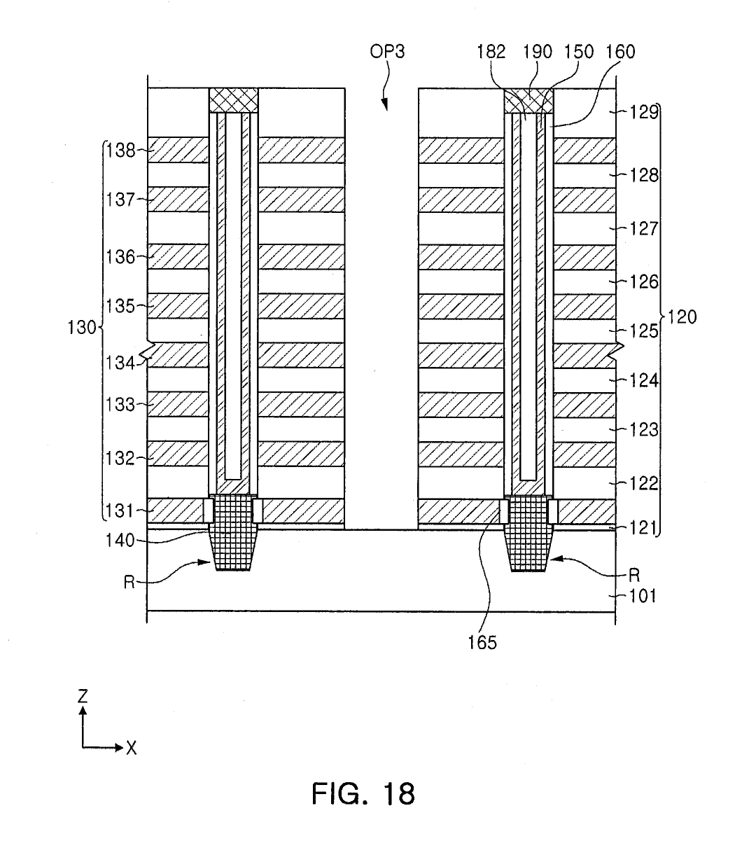

Referring to FIG. 18, the plurality of gate electrodes 130 may be formed within the lateral openings LP.

The gate electrodes 130 may include a metal material. In the present exemplary embodiment, the gate electrodes 130 may include, for example, W, Al, or Cu. According to exemplary embodiments, the gate electrodes 130 may further include a diffusion barrier layer (not shown). First, the diffusion barrier layer may be formed to uniformly cover the interlayer insulating layer 120 exposed by the second opening OP2 and the lateral openings LP, the gate dielectric layer 160, the epitaxial insulating layer 165, and the top surface of the substrate 101. Next, a metal material may be formed to fill the lateral openings LP.

Thereafter, a third opening OP3 may be formed by performing a mask forming process through an additional photolithography process and by removing the material forming the gate electrodes 130 formed within the second opening OP2 through an etching process, such that the gate electrodes 130 are disposed only within the lateral openings LP. The third opening OP3 may have a trench shape extending in the y direction (please refer to FIG. 10).

As a result, gate structures each including the interlayer insulating layers 120 and the gate dielectric layers 130 each of which is alternately stacked on the substrate 101 may be formed. The gate electrodes 130 may be exposed through lateral surfaces of the third opening OP3 formed between the gate structures. The gate structures may include the channels 150 penetrating through the interlayer insulating layers 120 and the gate electrodes 130 in a direction perpendicular to the top surface of the substrate 101. In addition, the gate structures may include the epitaxial layers 140 disposed on the substrate 101 below the channels 150, and the gate dielectric layers 160 disposed between the channels 150 and the gate electrodes 130. The gate dielectric layers 160 may each have a structure including the tunneling dielectric layer 162, the electric charge storing layer 164, and the blocking dielectric layer 166 sequentially stacked from the channel 150.

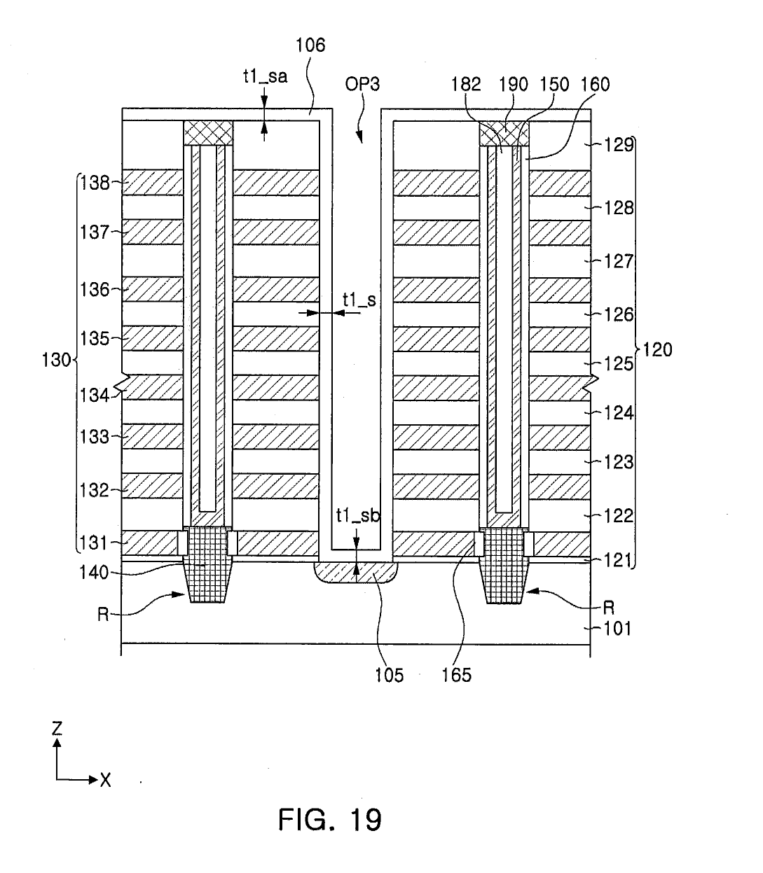

Referring to FIG. 19, the source area 105 may be formed in a portion of the substrate 101 exposed by the third opening OP3 between the gate structures, and the second insulating layer 106 covering an inner side wall of the third opening OP3 may be formed.

First, the source area 105 may be formed by ion injecting impurities into the substrate 101 exposed by the third opening OP3 using the gate structures as a mask. In a manner dissimilar thereto, the source area 105 may be formed after the formation of the second insulating layer 106, and may include a high-doped area and low-doped areas disposed at both ends thereof.

Next, the second insulating layer 106 may be formed to cover the inner side wall of the third opening OP3 between the gate structures. The second insulating layer 106 may be, for example, a silicon oxide, and the silicon oxide may be formed by performing the ALD process using the ALD apparatus illustrated in FIG. 1.

Referring to FIGS. 1 through 3, the substrate 101 having the third opening OP3 formed therein may be loaded in the first process chamber 20 in operation S10, and a silicon source gas may be supplied to the first process chamber 20 in a pulse during a predetermined period of time in operation S11. The silicon source gas may be an organic or inorganic compound including a silicon element. The silicon source gas may include, for example, HCDS, DIPAS, or the like. The silicon source gas may be supplied to the substrate 101 through the second process chamber 32 provided on the first process chamber 20. In this instance, a state in which plasma is not formed in the second process chamber 32 may be maintained therein. In other words, high frequency power may not be supplied to the plasma antenna 34 while the silicon source gas is being supplied to the first process chamber 20. The silicon source gas may be adsorbed onto the inner side wall of the third opening OP3, the substrate 101 exposed by the third opening OP3, and the <top surface of the upper most interlayer insulating layer 129. In operation S12, a first purge gas may be injected to the first process chamber 20 to perform a first purging process therein. The first purge gas may be supplied to the first process chamber 20 through the purge gas supply unit 60 provided on the side of the first process chamber 20. A silicon source gas which is not adsorbed may be discharged through the exhaust port 70 by the first purging process in operation S12.

In operation S13, an oxygen source gas may be supplied to the second process chamber 32 through the source gas supply unit 50 to be converted into a plasma state. The oxygen source gas may be selected from the group consisting of O₂, O₃, H₂O, and H₂O₂. In operation S14, only a radical component in the oxygen source gas in the plasma state may be supplied to the first process chamber 20 in a pulse during a predetermined period of time. The oxygen source gas in a radical state having a high reactivity may react with the silicon source gas to form the silicon oxide having a thickness of an monolayer conformally on the inner side wall of the third opening OP3, the substrate 101 exposed by the third opening OP3, and the top surface of the upper most interlayer insulating layer 129. In operation S15, a second purge gas may be supplied to the first process chamber 20 to perform a second purging process therein. An oxygen source gas which does not react and reaction byproducts may be discharged through the exhaust port 70 by the second purging process in operation S15.

By repeatedly performing operations S11 through S15 based on a desired thickness of the second insulating layer 106, the second insulating layer 106 formed of the silicon oxide may be formed.

The source area 105 may be exposed by removing a portion of the second insulating layer 106 using the anisotropic etching process. As a result, the second insulating layer 106 covering lateral surfaces of the gate structures, that is, the inner side wall of the third opening OP3 may be formed. The anisotropic etching process may be, for example, a reactive ion etching (RIE) process.

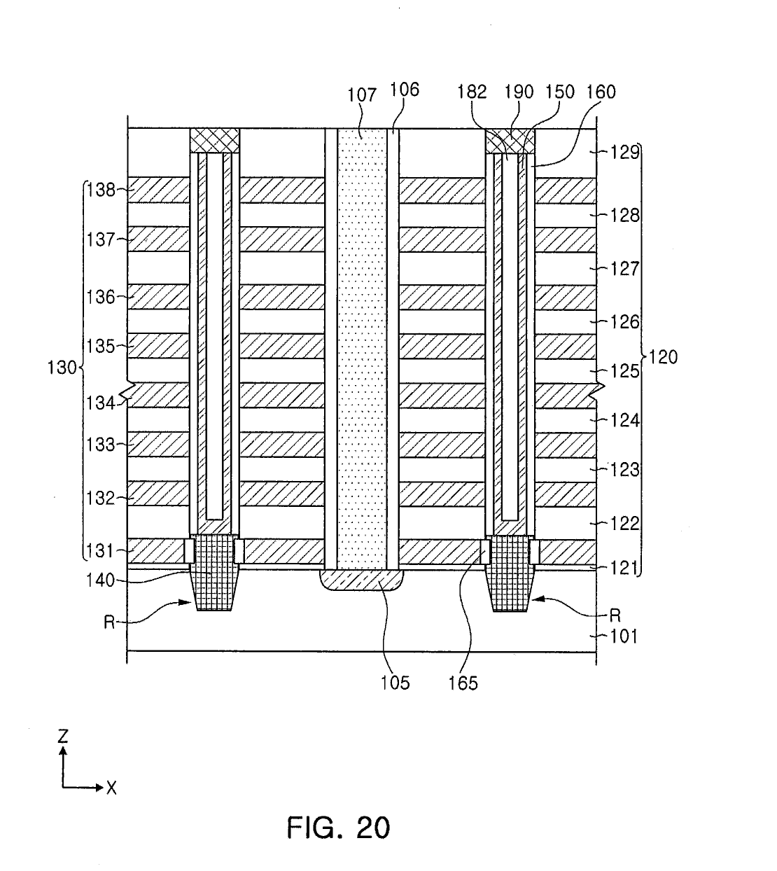

Referring to FIG. 20, the common source line 107 electrically insulated from the plurality of gate electrodes 130 by the second insulating layer 106 on the source area 105 may be formed.

A process of forming the common source line 107 may include a process of filling, with a conductive material, the third opening OP3 having the lateral surfaces on which the second insulating layer 106 is formed, and a CMP process of exposing top surfaces of the respective uppermost interlayer insulating layer 129 and drain pad 190.

Such a conductive material may include, for example, a metal material, a metal nitride material, and a metal silicide material. The common source line 107 may include, for example, W.

Although not illustrated in FIG. 19, an insulating layer covering the common source line 107, the drain pad 190, and the uppermost interlayer insulating layer 129 may be formed. A conductive contact plug may be formed within the insulating layer so as to be in contact with the drain pad 190. Bit lines BL may be formed on the insulating layer. The drain pad 190 may be electrically connected to the bit lines BL formed on the insulating layer through the conductive contact plug.

As set forth above, according to exemplary embodiments of the present inventive concept, a plasma generating unit may be provided to supply at least one source gas in a radical state to enhance a level of reactivity of source gases, and conformally deposit a high-quality thin film having a relatively uniform thickness in a pattern having a high aspect ratio.

In addition, since the plasma generating unit provides only a radical component from among components constituting plasma to a substrate, damage to the thin film and the substrate due to ions may be prevented.

Various advantages and effects in exemplary embodiments of the present inventive concept are not limited to the above-described descriptions and may be easily understood through explanations of concrete embodiments of the present inventive concept.

While exemplary embodiments have been shown and described above, it will be apparent to those skilled in the art that modifications and variations could be made without departing from the scope of the present inventive concept as defined by the appended claims.

What is claimed is:

1. An atomic layer deposition (ALD) apparatus, comprising:
a first process chamber;
a plasma generating unit provided outside of the first process chamber;
a source gas supply unit provided on an upper portion of the plasma generating unit, and configured to supply a plurality of source gases;
a purge gas supply unit configured to supply a purge gas to the first process chamber; and
a gas control unit configured to control the supply of the source gases and the purge gas,
wherein the plasma generating unit comprises a second process chamber having a space in which plasma is generated, and a plasma antenna configured to induce a magnetic field in the second process chamber, and
wherein the source gases are supplied to the first process chamber through the plasma generating unit.

2. The ALD apparatus of claim 1, wherein the second process chamber is formed of an insulating member and has a cylindrical shape, the plasma antenna is coiled around an outer circumferential surface of the second process chamber, and at least one of the source gases is supplied to the first process chamber in a radical state by the plasma generating unit.

3. The ALD apparatus of claim 1, wherein the plasma generating unit forms a plurality of plasma areas which are vertically spaced apart from one another along a central axis of the second process chamber.

4. The ALD apparatus of claim 3, wherein ions of the source gases are confined within the second chamber by the plurality of plasma areas.

5. The ALD apparatus of claim 1, wherein the plasma generating unit generates the plasma using an inductively coupled plasma (ICP) scheme.

6. The ALD apparatus of claim 1, further comprising:
a high frequency power supply unit configured to supply high frequency power to the plasma antenna; and
an impedance matching unit configured to perform impedance matching between the plasma antenna and the high frequency power supply unit.

7. The ALD apparatus of claim 1, wherein the source gas supply unit supplies the plurality of source gases in independent pulses via a respective plurality of source gas lines.

8. The ALD apparatus of claim 1, wherein the first process chamber includes a susceptor configured to receive a substrate, and
wherein the plasma generating unit is disposed on an upper portion of the first process chamber, and is spaced apart from the susceptor, such that the plasma generated within the plasma generating unit is not in direct contact with the substrate.

9. The ALD apparatus of claim 8, wherein the plasma generating unit supplies the plurality of source gases from the upper portion of the first process chamber to the substrate.

10. The ALD apparatus of claim 8, wherein the plasma generating unit is disposed on a side of the first process chamber, and supplies the plurality of source gases from the side of the first process chamber to the substrate.

11. The ALD apparatus of claim 1, wherein the plasma generating unit includes a plurality of plasma generating units, such that the plurality of different source gases are supplied to the first process chamber in a radical state.

12. An atomic layer deposition (ALD) apparatus, comprising:
a first process chamber; and
a plasma generating unit configured to supply a plurality of different source gases to a substrate located within the first process chamber, and supply at least one of the plurality of different source gases to the first process chamber in a radical state,
wherein the plasma generating unit comprises a second process chamber formed of an insulating member and having a cylindrical shape, and a plasma antenna coiled around an outer circumferential surface of the second process chamber, and wherein the plasma generating unit forms a plurality of plasma areas vertically spaced apart from one another along a central axis of the second process chamber.

13. The ALD apparatus of claim 12, wherein the plurality of plasma areas include three areas, and wherein a plasma area disposed in a center thereof has a highest level of potential.

14. The ALD apparatus of claim 12, wherein the plasma antenna is connected to a high frequency power supply unit configured to supply high frequency power, and is wound to have a length corresponding to a wavelength of the high frequency power.

15. The ALD apparatus of claim 12, wherein the substrate includes a channel hole pattern having a high aspect ratio, and wherein a thin film deposited on the substrate is a gate dielectric layer.

16. An atomic layer deposition (ALD) apparatus, comprising:
a first process chamber;
a plasma generating unit disposed adjacent to the first process chamber and interconnected with the first process chamber via a connection unit;
a source gas supply unit provided on an upper portion of the plasma generating unit, and configured to supply a plurality of sources gases to the first process chamber; and
a purge gas supply unit provided on an upper portion of the first process chamber, and configured to supply a purge gas to the first process chamber.

17. The ALD apparatus of claim 16, further comprising a gas control unit configured to control the supply of the source gases and the purge gas.

18. The ALD apparatus of claim 16, wherein the plasma generating unit comprises a second process chamber having a space in which plasma is generated, and a plasma antenna configured to induce a magnetic field in the second process chamber.

19. The ALD apparatus of claim 18, wherein the second process chamber has a cylindrical shape and the plasma antenna is coiled around an outer circumferential surface of the second process chamber.

20. The ALD apparatus of claim 18, wherein the plasma generating unit forms a plurality of plasma areas which are vertically spaced apart from one another along a central axis of the second process chamber.
